(19) United States
(12) Patent Application Publication
(10) Pub. No.: US 2003/0058909 A1
(43) Pub. Date: Mar. 27, 2003

(54) Method and apparatus for fabricating semiconductor lasers

(75) Inventor: William Benyon, Ottawa (CA)

Correspondence Address: GOWLING LAFLEUR HENDERSON, LLP, Suite 2600, 160 Elgin Street, Ottawa, ON, K1P 1C3, CA

(73) Assignee: Nortel Networks Limited

(21) Appl. No.: 10/196,956

(22) Filed: Jul. 18, 2002

Related U.S. Application Data
(60) Provisional application No. 60/306,190, filed on Jul. 19, 2001.

(51) Int. Cl. H01S 5/00; H01L 21/66; G01R 31/26

(52) U.S. Cl. 372/43; 438/16

(57) ABSTRACT

A method and system for fabricating semiconductor lasers includes the determination of a statistical predictive relationship between attribute measurements and mode index values for lasers fabricated according to a design. The predictive relationship predicts a specific mode index value using a specific attribute measurement. The predictive relationship may be applied in a fabrication process for lasers subsequently fabricated according to the design, and an appropriate grating structure providing increased production of lasers that lase at substantially target wavelengths is enabled.

### BACKGROUND OF THE INVENTION

Semiconductor lasers operating between wavelengths 1300 and 1550 nanometers are the preferred choice for optical fibre transmission systems.

The lasing wavelength of a semiconductor laser is substantially determined by three considerations: 1) doping, composition and thickness of the grown layers, 2) geometrical considerations such as-ridge width and depth, and 3) the period of the grating etched into the laser. “Crystal growth” relates to the epitaxial growth of layers on the substrate. “Geometric effects” relates to dimensional, and other structural characteristics of a semiconductor laser. These considerations contribute to an effective refractive index of the optical mode (“mode index”) within the laser cavity. This mode index determines the lasing wavelength of the laser.

Semiconductor laser designers use theoretical models to predict the mode index of the laser needed to lase at a particular wavelength. The designer models the mode index of the laser from first principles using physics. He or she calculates the effect of various properties and geometries on the optical and electrical properties of the laser. These properties such as bandgap, stress, layer thickness, doping, and the like, are controlled by the process of crystal growth.

Subsequent processing and geometric effects may also affect these properties. For example, a semiconductor laser of the appropriate photoluminescence wavelength will lase at a wavelength described by the following equation:

λ=2nΛ

where “n” is the mode index of the laser and Λ is the grating period provided on the laser. Gratings may be etched into certain layers in the wafer during fabrication. The gratings may provide gain and index coupling in the laser, depending on the design. By providing gratings of an appropriate period, a semiconductor laser may be fine-tuned for a particular wavelength. However, the actual mode index of a given laser cannot be known prior to electro-optic testing, where the actual lasing wavelength is measured.

In practice, the crystal growth process cannot be precisely controlled. Variations in the course of growth and fabrication results in variations of mode index from wafer to wafer, even within the same reactor run. Variations include actual layer composition, actual layer thickness, the presence of impurities, and the like. As such, the actual mode index of a fabricated laser often varies from the estimated mode index. Correspondingly, the actual lasing wavelength of a fabricated laser varies from the target lasing wavelength, although the majority of semiconductor lasers fabricated according to a design may be made to lase within approximately 5 nanometers of the target wavelength.

However, manufacturing specifications may require that the actual lasing wavelength to be within a few nanometers of the targeted wavelength λₜ, for example, ± about 1.8 nanometers. Wafers that do not meet specifications may be rejected. Depending on the accuracy of the estimates, the number of wafers, and hence lasers, that are rejected may be substantial.

Previously, the gratings fabricator estimated the mode index for a given fabrication run of lasers using historical data obtained from previously fabricated lasers made according the same design. Using this estimate, a further guess was made as to the appropriate grating period required to bring the lasing wavelength closer to the target lasing wavelength. The estimated grating period would then be applied in the fabrication process. On substantial completion of fabrication, the lasing wavelength would be measured and recorded.

Since the mode index may vary from wafer to wafer and run to run, there is no guarantee of the accuracy of the guess. Sampling of growth runs may indicate an interpolated estimate is appropriate (assuming the relationship is linear), but there is no guarantee that the samples taken are indicative of the remaining lasers in the growth run. As a result, the inventory of sampled lasers is large, resulting in lower yield per fabrication run. Further, wafers from the same growth run cannot be fabricated until the results of opto-electric testing are known.

### BRIEF SUMMARY OF THE INVENTION

The present invention seeks to provide a method and system of fabrication of semiconductor lasers, which minimizes the above problems.

According to an aspect of the invention, there is provided a method and system of fabricating semiconductor lasers based on: obtaining mode index values for a number of lasers fabricated according to a design; obtaining attribute measurements for those lasers; and determining a predictive relationship using a statistical analysis between the attribute measurements and the mode index values. The relationship can be used to predict a specific mode index value when a specific attribute measurement has been obtained.

According to another aspect of the invention, there is also provided a method of fabricating semiconductor lasers using the statistical predictive relationship. In the course of fabricating semiconductor lasers according to the design, a specific attribute measurement may be obtained. Applying the statistical predictive relationship to the specific attribute measurement will yield a predicted specific mode index value for the laser. A grating structure can then be provided on the laser using the predicted specific mode index value.

In one embodiment of the invention, a predictive relationship involves determining a linear equation to relate the attributes of photoluminescence wavelength, quantum well and quantum barrier thickness and zero order mismatch to the mode index of semiconductor lasers fabricated according to a design. Using this linear equation, the mode index of lasers in the course of fabrication can be estimated after specific measurements for photoluminescence wavelength, quantum well and quantum barrier thickness and zero order mismatch are obtained.

In another embodiment of the invention, the grating period of a grating structure to be provided on a laser in the course of the fabrication, is provided using the specific mode index value as predicted using the predictive relationship.

The invention includes a statistical model derived from measured values to predict the lasing wavelength of a laser. During the fabrication of other semiconductor lasers that are similarly designed and manufactured, values are determined in relation to one or more attributes in order to estimate the mode index of lasers in a fabrication run. A grating structure may then be provided so as to fabricate semiconductor lasers that lase at substantially target wavelengths.

Advantageously, by improving the accuracy of the prediction of the mode index, an increased number of semiconductor lasers may be manufactured to lase at a targeted wavelength, or within specifications therefore.

### BRIEF DESCRIPTION OF THE DRAWINGS

Other aspects and features of the present invention will become apparent to those ordinarily skilled in the art upon review of the following description of specific embodiments of the invention in conjunction with the accompanying figures in which:

FIG. 1 is a flow chart of a general fabrication process.

FIG. 2a is a cross-section of a generic wafer following a first growth of layers.

FIG. 2b is the wafer of 2a with a grating structure provided.

FIG. 2c is the wafer of 2b following a second growth of layers.

FIG. 3 is a diagram of a generic process for providing a grating structure.

FIG. 4a is a flow chart of an initial method involving one attribute in accordance with an embodiment of the invention.

FIG. 4b is a flow chart of a subsequent method involving one attribute in accordance with another embodiment of the invention.

FIG. 5 is a flow chart of an initial method in accordance with yet another embodiment of the invention.

FIG. 6 is a schematic view of a close-up cross-section of a generic wafer following first growth layers.

FIG. 7 is schematic view of a cross-section view of a generic wafer following the second growth layers following the provision of grating structure.

Similar references are used in different figures to denote similar elements.

### DETAILED DESCRIPTION OF THE INVENTION

The fabrication of semiconductor lasers has as one of its objectives the consistent production of lasers that lase at a target wavelength. The fabrication process involves both a process of crystal growth, and the provision of a grating structure. The process of crystal growth can yield lasers that lase in a desired spectrum, while grating adjustments during the fabrication process further adjusts and narrows the lasing wavelength to substantially the target wavelength to a greater degree.

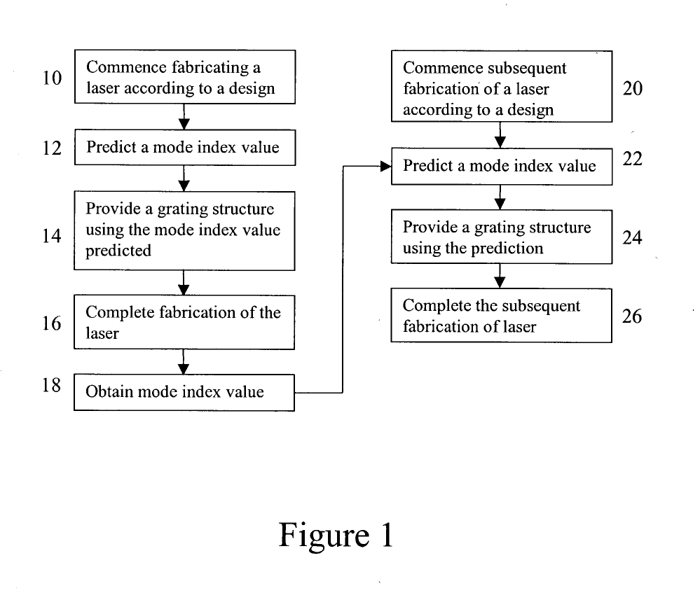

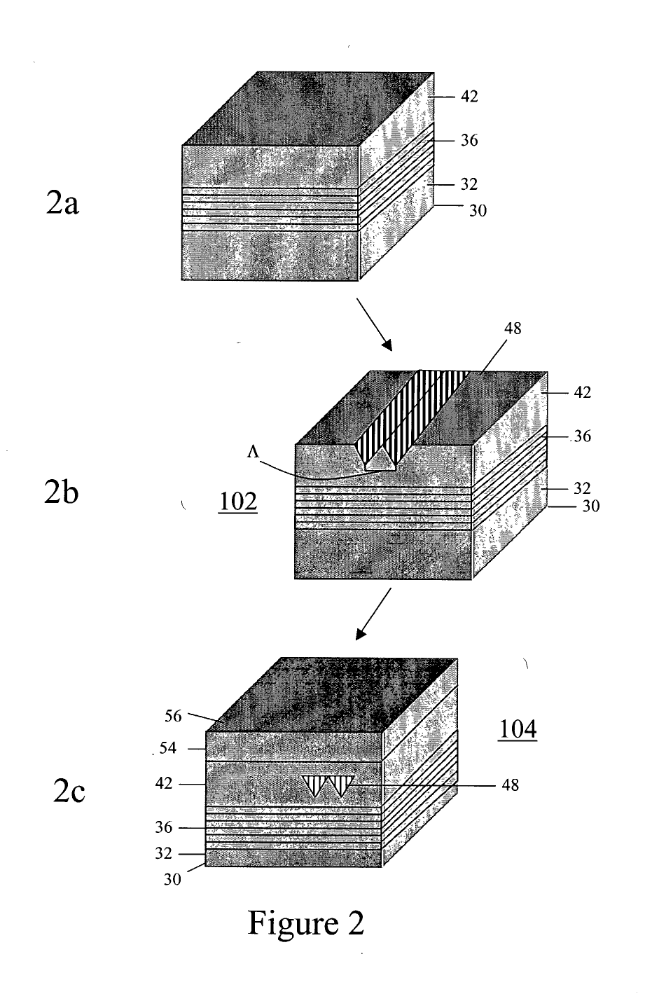

Referring to FIGS. 1 and 2, an overview of a generic fabrication process and a cross-section of a generic semiconductor laser wafer are provided as background for understanding the invention. The first step in FIG. 1 is to commence fabricating a laser according to a design 10, which begins with the process of crystal growth. The process of crystal growth follows a design involving a particular material system, usually involving III-V compounds. For example, material systems for fabrication of semiconductor lasers include: Gallium Arsenide (GaAs) and Indium Gallium Arsenide Phosphide (InGaAsP). The lasing wavelength of a semiconductor laser is related to the material system selected; for example, a laser based on GaAs generally operates at around 800 to 950 nanometers, while a laser based on InGaAsP generally operates at around 1300 to 1600 nanometers.

Depending on the material system, a substrate 30 (or laser material), depicted in FIG. 2, is selected, for example, InP, GaAs, or other crystalline material. For example, very thin layers 32, 36 and 42 of semiconductor material whose crystallinity matches that of the substrate 30 (lattice matched) are then epitaxially grown on top of the selected substrate wafer 30 in a first growth of layers as depicted in FIG. 2a. For example, GaAlAs may be grown on a GaAs substrate or InGaAsP may be grown on an InP substrate. Using various conventional methods including molecular-beam epitaxy (MBE), liquid-phase epitaxy (LPE), and chemical vapour deposition (CVD), layer after layer of semiconductor material is deposited on the preceding layer. Ultimately, the substrate 30 with epitaxial layers 32, 36, 42, and 54, will be processed to form a number of semiconductor lasers.

The process of crystal growth may be used to vary physical characteristics of the layers, for example, composition, stress, doping levels, thickness, and the like. These characteristics impact on the overall optical and electrical properties of the structure. For example, to design a layer possessing approximate bandgap energies, a number of different techniques may be employed including: varying the proportion of constituent elements in the layers, varying the degree of p- or n-doping in a layer, varying the thickness of each layer providing sub-layers within layers, and the like.

The physical characteristics of other layers, for example, adjacent layers or regions of multiple layers, impact the overall optical electrical properties of the structure. For example, by sandwiching layers of semiconductor material between lattice-matched material of a different composition, and repeating the process, the bandgap energy of a layer may be further modified to form an active region consisting of multiple sublayers 36, where stimulate emission may occur.

Based on the design, historical data and experience, a fabricator can make a prediction as to the mode index value 12 (FIG. 1), of a laser fabricated according to the particular design.

Processing techniques may then be applied to bring the actual lasing wavelength closer to the desired target wavelength, at least within acceptable limits therefore, for example, within ±1.8 nanometers.

A grating structure 48 may be provided through certain epitaxial layers 42 during the fabrication process, as depicted in FIG. 1. The grating structure 48 includes periodic, or regularly spaced, etched grooves having a grating period Λ.

The grating period Λ is related to the lasing wavelength by the relationship:

Λ=λ/2n

Knowing the desired lasing wavelength and estimating the mode index value, an appropriate grating period may then be selected to best yield the targeted wavelength.

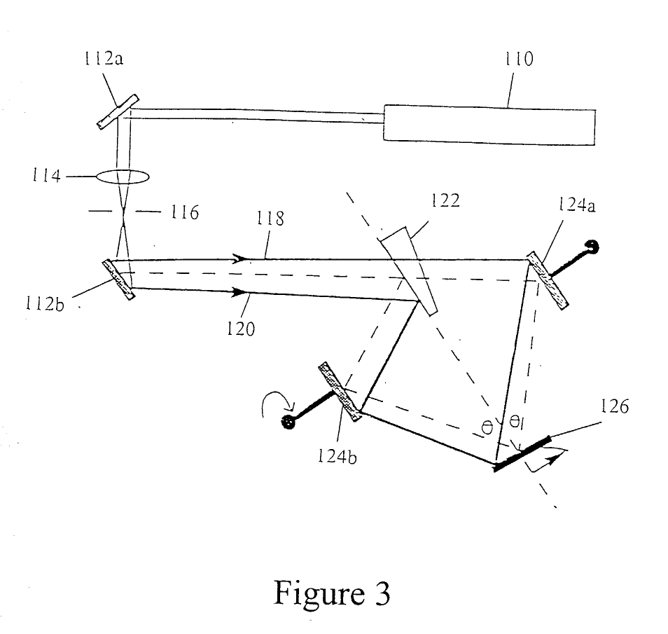

Conventionally, formation of the grating structure 48 involves the exposure of a desired region of a photoresist coated wafer to interfering light. For example, the resist coated wafer with a number of epitaxial layers grown thereon is mounted in a laser holography system as exemplified in FIG. 3, and exposed to inferring beams of light. Where the light arrives in-phase constructive interference produces bands of maximum intensity on the wafer surface. The distance between maxima on the wafer is the period of grating (Λ). The photoresist is then developed and the grooves are etched using conventional etching process. The holography system can be set so as to generate the correct interference pattern to yield the desired grating period.

FIG. 2b depicts a wafer after a grating structure has been provided. After the grating structure 48 is provided, the fabrication of the laser is completed 16 (FIG. 1) by the epitaxial growth of the remaining layers and sublayers 42, 54 and 56. FIG. 2c depicts a laser following completion of the second growth of layers. The final lasing wavelength may then be measured and the actual mode index value obtained during electro-optic testing.

The period of the grating can be controlled to 0.05 nanometers in approximately 235 nanometers, across the full wafer, an accuracy of 99.98%. When the actual lasing wavelength of a finally fabricated laser is measured, there is often still a degree of variation between targeted and actual lasing wavelength, and between estimated and actual mode index value caused by crystal growth and fabrication variations. Traditionally, the gratings fabricator will take note of the variation and adjust the grating period in the next grating run accordingly, as depicted in steps 20, 22, 24, and 26, of FIG. 1.

Keeping this background in mind, it is known that each semiconductor laser, during and subsequent to fabrication, possesses certain identifiable and measurable characteristics and properties or attributes (collectively “attributes”). Without limitation, these attributes include the composition of the substrate; the number of and thickness of layers; the doping levels and composition of each layers; the order of the layers; the composition of quantum well layers; the composition of the quantum barrier layers; the thickness of each quantum well layer; the thickness of each quantum barrier layer; the strain of the quantum well and quantum barrier layers; the period of the grating etched; and the like. Information regarding these attributes is typically collected during and subsequent to the fabrication process.

For example, during fabrication, one or more wafers may be removed from a growth chamber, tested, and measurements collected respecting various attributes. One typical attribute measured on sampled wafers is the photoluminescence (PL) wavelength, which measures the peak wavelength of light that passes through and is emitted from the wafer after first growth. The PL of all regions of a sampled wafer is measured and the information is recorded.

Another attribute that may be measured on a sampled wafer is the thickness of the quantum well layers and quantum barrier layers (QW and QB thickness) of the active region 36. This may be measured by X-ray diffraction and the information recorded.

Information relating to the thickness weighted average strain of the quantum well layers and quantum barrier layers (zero-order mismatch (ZOM)) may also be measured by X-ray diffraction and recorded for each sample wafer.

In addition to the attributes of PL, QW and QB, and ZOM, other attributes measured may include particular dimensions, composition, conductivity, layer thickness, and the like.

Substantial amounts of information is often available from fabricators regarding attributes of lasers of a particular design for use in predicting a mode index value, and hence, actual lasing wavelength. This information is available for use to improve the fabrication process as follows.

Attribute measurements for one or more attributes for each of a number of lasers all fabricated in accordance with a particular design for lasing at a particular target wavelength, can be compiled and a correlation with the actual mode index values determined.

For example, measured values for a number of attributes are entered into a database application; for example, Filemaker Pro® or Microsoft Excels®, to create a data set. This is repeated respecting the same attributes for each of a number of other lasers fabricated according to the same design. In addition, for each of the finally fabricated lasers, the actual lasing wavelength as measured and the actual mode index value as determined, are also included in the data set. This process may be repeated to compile attribute measurements, lasing wavelength and mode index values for each of a number of wafers in the data set.

A partial example of a data set may include:

| | | Mode Index | | | Photolumi- |
|---|---|---|---|---|---|
| | | (Calculated | QWQB | | nesence (PL) |
| Laser/ | Grating Period | From Lasing | Thickness | ZOM | Wavelength |
| Run ID | (Measured) | Wavelength) | (measured) | (measured) | (measured) |
| 1: Run 1 | 239.09 | 3.19743 | 154 | −915.2 | 1509.05 |
| 4: Run 1 | 239.17 | 3.193593 | 153 | −938.6 | 1511.39 |
| 2: Run 3 | 239.17 | 3.19565 | 153 | −948.7 | 1514.65 |
| 4: Run 3 | 239.82 | 3.195378 | 154 | −960 | 1516.71 |
| 7: Run 3 | 240.23 | 3.193594 | 154 | −962.3 | 1519.31 |
| 3: Run 7 | 239.4 | 3.195057 | 155 | −945.7 | 1515.89 |

As will be appreciated, the data set compiled may be in respect of a sampling of wafers, for example, one or more wafers per reactor run or one or more wafers for every fifth reactor run. Generally, however, the larger the sample size, the more complete the data set and the more accurate the results. Historical empirical data from previously fabricated and measured wafers may also be used, where the wafers were fabricated in accordance with the same or substantially the same design.

Statistical factor analysis may be used to reduce and classify the number attributes considered so as to permit selection of one or more attributes which most closely correlate with the actual mode index values and to identify those attributes which bear less, little or no correlation. From the data set, the degree of correlation between the measurement values for any particular attribute and the actual mode index may be determined, for example, by using conventional statistical analyses, eg. Pearson correlation. Among others, analysis of variance (ANOVA) and multivariate analysis of variance (MANOVA) may be used. Statistical software applications may be used including SAS Jump® and STATISTICA® to facilitate statistical analyses.

A statistical predictive relationship may be determined between attributes and mode index values so as to allow prediction of a mode index value where one or more attribute measurements are obtained. Alternatively, the predictive relationship may be determined respecting one or more attributes bearing an acceptable degree of correlation.

For example, a conventional statistical regression analysis may be performed on the data set as compiled to determine a relationship between attribute measurements to mode index values. For a linearly related attribute, a regression analysis computes a line such that squared deviations are minimized. The regression line sets out a prediction of the dependent variable (Y), given the independent variables (X). The regression line is defined by the equation:

Y=a+b*X

The Y variable can be expressed in terms of a constant a and a slope b times the X variable, where a is the intercept, and the slope b is the regression coefficient. For example, the variable Y may be the actual mode index value ηₐ and the variable X may be the attribute photoluminescence wavelength.

Additionally, multiple regression analysis may be used in respect of the measured values for multiple attributes selected and the corresponding mode index values. In general, multiple regression will calculate an estimate linear equation of the form:

Y=a+b₁X₁+b₂X ₂+ . . . +bₙXₙ

where the X terms refer to various variables (in this case, attributes) and the b coefficients represent the respective regression coefficients.

It will be appreciated that the equation calculated to estimate the mode index is specific to the data set used, which in turn is dependent on the specific semiconductor laser design and fabrication process. Depending on the attribute or attributes selected to be compiled into a data set in relation to a particular design, other attributes may be more or less correlated to mode index. Fewer or more attributes may be included in determining the relationship to estimate mode index. Further, the equation describing the relationship between the attribute(s) selected and the mode index may be more accurately described by a non-linear equation.

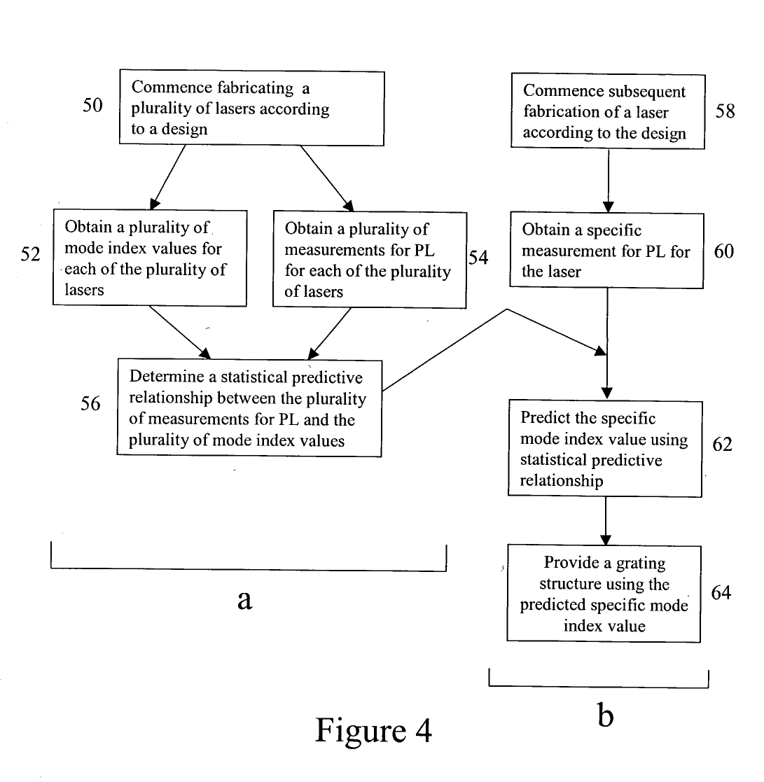

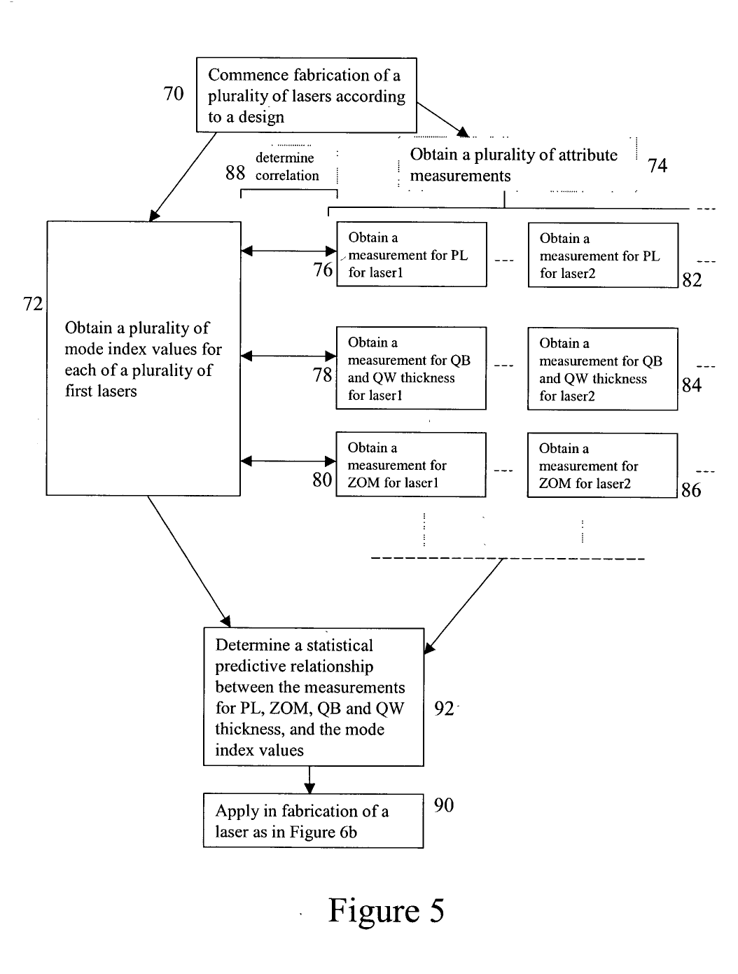

The above steps in determining a statistical predictive relationship between attribute measurements and mode index values are set out in FIG. 4a and FIG. 5. In FIG. 4a, the predictive relationship is determined with reference to the single attribute PL. In FIG. 5, the predictive relationship is determined with reference to a number of attributes including PL, QW and QB thickness, ZOM, and other attributes.

The resulting equation may then be used in subsequent fabrication runs of semiconductor lasers on the same design to estimate a mode index of the lasers manufactured in a fabrication run, following obtaining measurements respecting particular attributes correlated to mode index, for example, as depicted in FIG. 4b. Based on the estimated mode index, the grating period to be applied to the wafers in the fabrication run may be appropriately selected so as to fine-tune the lasing wavelength. In this manner an increased number of lasers that lase at a wavelength within specifications may be produced.

To facilitate a greater understanding of the invention, reference will now be made to a detailed sample laser and a description of the steps of manufacture. As will be appreciated, the invention is not limited to the specific structure, design or fabrication process disclosed, but rather this example is provided to facilitate an understanding of the invention.

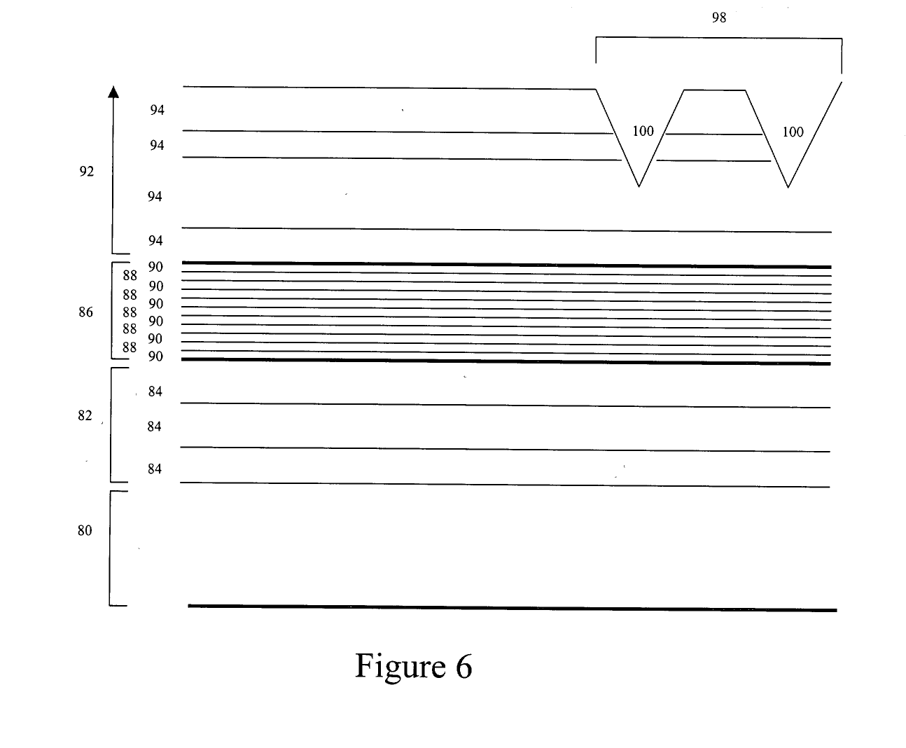

Referring to FIG. 6, there is depicted a cross-section of a portion of a generic semiconductor laser wafer, partially fabricated, following first growth of crystal layers, for example, as in FIG. 2a, fabricated in accordance with a particular design. The wafer is one of a number of prefabricated substrate wafers loaded into a multi-wafer reactor, for example, a commercially available metal-organic chemical vapour deposition (MOCVD) reactor. Typically, 8 to 10 wafers are included per reactor run. This, and other wafers similarly fabricated, will be a source of attribute information, as will be described later.

Various layers of semiconductor material are epitaxially grown onto the substrate using conventional reactant mixtures in predetermined proportions, as selected by designers to yield the desired composition mixture. Growth is terminated by suspending the reactive gas flows and removing excess gas reactants.

In the sample structure shown in FIG. 6, first growth includes growth of the layers of a first confinement region 82 over top of the substrate 80, followed by growth of the active region 86 and several layers of the second confinement region 92.

More particularly, an n-doped InP substrate layer 80 is overlayed with an n-doped first confinement region 82, which includes multiple layers of n-doped InGaAsP confining layers 84. The confining layers 84 are designed to yield a desired bandgap energy of the region, and thus may vary in number, thickness, composition, doping levels, etc.

An active region 86 includes five compressively strained Silicon doped (Si) quantum well layers 90 separated by four Zinc (Zn) doped unstrained quantum barrier layers 88 and is grown next overlying the first confinement region. The quantum well layers 90 vary in thickness, doping, composition, energy, and the like, from the quantum barrier layers 88, as predetermined by designers to provide the required bandgap for light emission at more or less the desired target wavelength.

To provide carrier and light confinement, the active region 86 of the laser is designed and layered such that the refractive index is higher and bandgap energies of the active region 86 are lower than that of the adjacent n- and p-doped confinement regions 82 and 92.

A p-doped second confinement region 92 comprising multiple layers 94 of p-doped material is also designed to yield a desired bandgap energy for the region. Techniques employed include variations in the number, thickness, composition, doping levels, and the like, of layers and may also include sandwiching and repeating of layers, for example, sandwiching p-doped InGaAsP layers with p-doped InP layers. In the sample laser structure depicted, several layers 94 of the second confinement region 92 are grown over the active region 86.

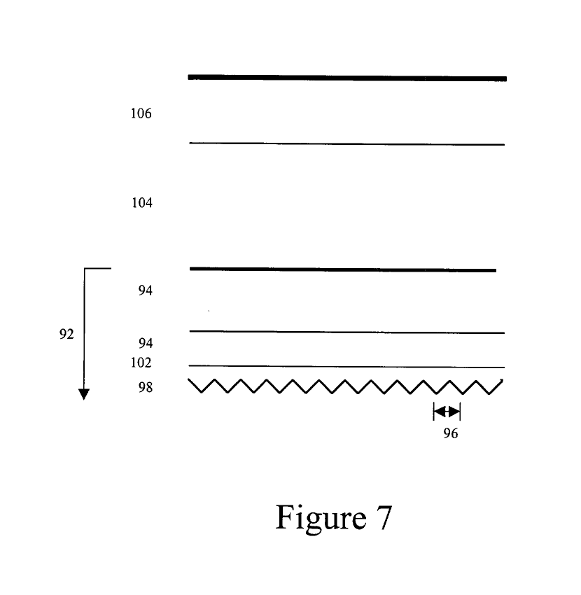

Following first growth, referring to FIG. 7, a grating structure 98 is patterned in certain layers of the second confinement region 92. A grating structure 98 includes coplanar substantially parallel regularly spaced etched grooves 100 defined through one or more layers in the second confinement region 92. The period 96 of the grooves is selected to define a first order grating for the lasing wavelength. As will be appreciated by persons skilled in the art, the grating structure 98 may be patterned through all or some of the layers of the second confinement region 92, all or some of the layers of the active region 86, or even into the first confinement region 82. The grating structure 98 may be varied in period, depth, position, location, etc. to yield the desired refractive index differences between regions within the wafer.

To apply a grating structure 98, a wafer is removed from the growth chamber after the appropriate layers have been grown. For example, a dielectric such a SiO₂ may be grown on the surface of the wafer, after several layers of the second confinement region have been grown, and the groove pattern created in the dielectric layer. Alternatively, only photoresist is used on the pattern created in it. Photoresist is spin coated onto the wafer and baked.

In initial runs, the desired period of the grating structure 98 is based on a best guess of the expected mode index value of a laser fabricated according to the design. The steps in the crystal growth process thus far are assessed, as is past experience.

The resist coated wafer is mounted in a laser holography system as exemplified in FIG. 3, and exposed to a He:Cd laser 110. The laser beam is spatially filtered, passed via mirrors 112a and 112b and collimating lens 114, as required, through a pin-hole 116 and on through a beam splitter 112 whereby a transmitted beam 118 and a reflected beam 120 are generated. Adjustable holographic mirrors 124a and 124b reflect the two beams to cause the two beams to interfere in the desired pattern at the wafer surface 126 to yield the desired period. The grating period applied is recorded. The photoresist is developed and the grooves are etched using conventional etching process. The residual dielectric (if used) is then removed.

Referring to FIG. 2c and 7, a partially fabricated semiconductor laser device is provided with a second growth of crystal layers following the provision of the grating structure. The remaining layers of the second confinement region 92 are grown. Layers 94 comprising the p-doped InP layers sandwiching a thinner InGaAsP layer are grown over the grating structure 98 to complete the second confinement region 92. Second growth is completed by the growth over the second confinement region of a p-doped InP cladding layer 104, followed by InP p-doped capping layer 106, an undoped protective layer (not shown), which will be etched off following photolithography, and an electrical contact (not shown) subsequently attached thereto.

After first growth, the wafer is removed, tested and measured for attributes such as PL wavelength, QW and QB thickness, and the like, and the information recorded.

Following final fabrication, the actual lasing wavelength of the wafer is measured and the mode index is obtained.

The fabrication process is repeated for the fabrication of a number of lasers of the same design. Attributes measurements for a number of attributes including PL, ZOM and QB and QW thickness are collected for each laser or wafer. Also, the actual lasing wavelength for each is measured and the actual mode index value determined.

The attribute measurements, actual lasing wavelength, and actual mode index for each laser wafer are compiled into a data set. Correlation tests are then performed using the data set to determine the degree of correlation between each attribute and mode index.

Using actual data from measured attributes for lasers of similar design to FIGS. 6 and 7, it was determined that PL wavelength was the most dominant variable affecting the actual mode index ηₐ of the fabricated laser, having regard to the variable magnitude resulting in an F-ratio in the order of 740. In other words, this attribute demonstrated the greatest degree of relationship to the actual mode index ηₐ. The next most dominant attribute was ZOM with an F-ratio in the order of 279, and the next most important attribute is the QW and QB thickness with an F-ratio of 68.

Using the values for PL, QW and QB thickness and for ZOM, from the data set, the relationship between these attributes with the actual mode index values was determined using a regression analysis. The multiple regression analysis performed yielded a formula to estimate mode index ηₑ for lasers of the same (or substantially the same) design as follows:

ηₑ=3.46616−0.0002005*X₁+0.0001399*X₂−0.0001148*X₃

where X₁ is measured value for PL wavelength attribute, X₂ is the measured value for QW and QB thickness attribute, and X₃ is the measured value for ZOM attribute.

In later fabrication runs, the first epitaxial growth of layers (FIG. 2a) according to the design is commenced on wafer substrates 80. During fabrication, one or more wafers are removed for measurement or testing, and the values for PL wavelength, QW and QB thickness and ZOM determined. These values are used in the multiple regression line formula earlier derived for the particular laser design in order to estimate the mode index ηₑ.

Using the relationship between estimate mode index and grating period,

$$Λ = \frac{{λ}_{t}}{2 {η}_{e}}$$

where λₜ is the target lasing wavelength of the laser, and ηₑ is the estimated (or predicted) mode index, the grating period Λ 96 required to be etched to substantially achieve the target wavelength is more accurately estimated. The grating period Λ is then entered into the holography computer, and the angle of mirrors changed to establish the correct interference pattern.

After the grating structure 98 is applied, the wafer is returned to the reactor for the second epitaxial growth of layers (FIG. 2c). A layer of an appropriate compound 102, depending on the design, may be grown in the grating grooves 98 to make a flat surface. Remaining layers of the second confinement region 94 are grown over top of the grating structure (not shown), followed by any cladding layer (not shown) and capping layers.

Using the regression line formula derived for the particular data set, lasers were fabricated with a lasing wavelength within ±1.2 nm of the targeted wavelength 85% of the time, and within ±0.8 nm 70.8% of the time thereby resulting in greater productivity, greater accuracy, less waste, and higher yields per fabrication run.

The present invention has been described with regard to preferred embodiments. However, it will be obvious to persons skilled in the art that numerous modifications, variations, and adaptations may be made to the particular embodiments of the invention described above without departing from the scope of the invention, which is defined in the claims.

What is claimed is:

1. A method of fabricating semiconductor lasers, comprising the steps of:
obtaining a plurality of mode index values for a plurality of lasers fabricated according to a design;
a) obtaining a plurality of attribute measurements for the plurality of lasers; and
b) determining a statistical predictive relationship between the plurality of attribute measurements and the plurality of mode index values for predicting a specific mode index value using a specific attribute measurement.

2. A method of claim 1 further comprising the steps of:
i) obtaining a specific attribute measurement for a laser subsequently fabricated according to the design;
ii) applying the statistical predictive relationship to the specific attribute measurement to obtain a predicted specific mode index value for the laser; and
iii) providing a grating structure on the laser using the predicted specific mode index value.

3. A method of claim 1, wherein the plurality of attribute measurements are photoluminescence wavelength measurements.

4. A method of claim 1, wherein the plurality of attribute measurements are quantum well and quantum barrier thickness measurements.

5. A method of claim 1, wherein the plurality of attribute measurements are zero order mismatch measurements.

6. A method of claim 1 wherein the plurality of attribute measurements includes measurements for a plurality of attributes.

7. A method of claim 6, wherein the plurality of attributes include at least two of photoluminescence wavelength, quantum well and quantum barrier thickness, or zero order mismatch.

8. A method of claim 1, wherein the plurality of attribute measurements are statistically correlated to the plurality of mode index values.

9. A method of claim 1, wherein the statistical predictive relationship is an equation wherein mode index values are dependent variables and attribute measurements are independent variables.

10. A method of claim 9, wherein the equation is a linear equation.

11. A method of claim 8, wherein the linear equation is obtained by a regression analysis.

12. A method of claim 9, wherein the attributes measurements comprise a plurality of attributes each of which are independent variables.

13. A method of claim 12, wherein the equation is obtained from a multiple regression analysis.

14. A method of claim 1, wherein the specific attribute measurement includes a specific photoluminescence wavelength measurement.

15. A method of claim 1, wherein the specific attribute measurement includes a specific quantum well and quantum barrier thickness measurement.

16. A method of claim 1, wherein the specific attribute measurement includes a specific zero order mismatch measurement.

17. A method of claim 1 wherein the specific attribute measurement includes a specific measurement for each of a plurality of attributes.

18. A method of claim 17, wherein the specific measurement for each of a plurality of attributes includes a specific measurement for each of photoluminescence wavelength, quantum well and quantum barrier thickness and zero order mismatch.

19. A method of claim 2, wherein the specific attribute measurement includes a specific photoluminescence wavelength measurement.

20. A method of claim 2, wherein a specific attribute measurement includes a specific measurement for quantum well and quantum barrier thickness.

21. A method of claim 2, wherein a specific attribute measurement includes a specific zero order mismatch measurement.

22. A method of claim 2, wherein a specific attribute measurement includes a specific measurement for each of a plurality of specific attributes.

23. A method of claim 22, wherein the plurality of specific attributes includes photoluminescence wavelength, quantum well and quantum barrier thickness and zero order mismatch.

24. A method of claim 2, wherein providing the grating structure includes selecting a grating period using the predicted specific mode index value.

25. A method of claim 24, wherein the grating period is selected based on a target final lasing wavelength divided by two times the predicted specific mode index value.

26. A method of fabricating semiconductor lasers comprising the steps of:
a) obtaining a plurality of mode index values for a plurality of lasers fabricated according to a design;
b) obtaining a plurality of measurements for photoluminescence wavelength for the plurality of lasers;
c) obtaining a plurality of measurements for quantum well and quantum barrier thickness for the plurality of lasers;
d) obtaining a plurality of measurements for zero order mismatch for the plurality of lasers; and
e) determining a statistical predictive relationship between the plurality of measurements for photoluminescence wavelength, the plurality of measurements of quantum well and quantum barrier thickness, the plurality of measurements for zero order mismatch, and the plurality of mode index values for predicting a specific mode index value using a specific photoluminescence wavelength measurement, a specific quantum well and quantum barrier thickness wavelength measurement and a specific zero order mismatch measurement.

27. A method of claim 26 further comprising the steps of:
i) obtaining a specific photoluminescence wavelength measurement, a specific quantum well and quantum barrier thickness wavelength measurement and a specific zero order mismatch measurement for a laser subsequently fabricated according to the design;
ii) applying the statistical predictive relationship to the specific photoluminescence wavelength measurement, a specific quantum well and quantum barrier thickness wavelength measurement and a specific zero order mismatch measurement to obtain a predicted specific mode index value for the laser; and
iii) providing a grating structure on the laser using the predicted specific mode index value.

28. A system of fabricating semiconductor lasers comprising:
a) means for obtaining a plurality of mode index values for a plurality of lasers fabricated according to a design;
b) means for obtaining a plurality of attribute measurements for the plurality of lasers; and
c) means for determining a statistical predictive relationship between the plurality of attribute measurements and the plurality of mode index values for predicting a specific mode index value using at least one specific attribute measurement.

29. A system of claim 28 further comprising the steps of:
i) means for obtaining a specific attribute measurement for a laser subsequently fabricated according to a design;
ii) means for applying the statistical predictive relationship to the specific attribute measurement to obtain a predicted specific mode index value for the laser; and
iii) means for providing a grating structure on the laser using the predicted specific mode index value.
